(19) United States
(12) Patent Application Publication
(10) Pub. No.: US 2024/0250133 A1
(43) Pub. Date: Jul. 25, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Wu-Wei TSAI, Hsinchu (TW); Chi-Min CHEN, Hsinchu (TW); Yin-Hao WU, Hsinchu (TW); Kai-Wen CHENG, Hsinchu (TW); Hai-Ching CHEN, Hsinchu (TW); Yu-Ming LIN, Hsinchu (TW); Chung-Te LIN, Hsinchu (TW)

(73) Assignee: Taiwan Semiconductor Manufacturing Company, Ltd., Hsinchu (TW)

(21) Appl. No.: 18/099,146

(22) Filed: Jan. 19, 2023

Related U.S. Application Data
(60) Provisional application No. 63/411,827, filed on Sep. 30, 2022.

(51) Int. Cl. H01L 29/417; H01L 29/40; H01L 29/66; H01L 29/786

(52) U.S. Cl. CPC H01L 29/41733; H01L 29/401; H01L 29/66969; H01L 29/7869

(57) ABSTRACT

A semiconductor device and a manufacturing method thereof are provided. The semiconductor device includes a gate electrode, a gate insulating layer, an active layer, a dielectric layer, a source electrode, and a drain electrode. The gate insulating layer is disposed between the gate electrode and the active layer, the dielectric layer is disposed on a side of the active layer, and the source electrode and the drain electrode pass through the dielectric layer to electrically connect with the active layer, wherein a first contact surface is formed between the source electrode and the active layer, a second contact surface is formed between the drain electrode and the active layer, the first contact surface and the second contact surface are subjected to a plasma treatment or a deposition treatment to form a protective interface layer.

### PRIORITY CLAIM AND CROSS-REFERENCE

This application claims the benefit of U.S. provisional application Ser. No. 63/411,827, filed Sep. 30, 2022, the subject matter of which is incorporated herein by reference.

### BACKGROUND

Conventional manufacturing method of a semiconductor device generates contact regions of source and drain electrodes of a thin film transistor (TFT) by chemical vapor deposition (CVD) or physical vapor deposition (PVD). However, the oxygen vacancies generated on the surface of the active layer due to plasma damage caused by CVD or PVD has a negative impact on the performance of the thin film transistor, and will result in a decrease in the reliability of the thin film transistor, and thus it is needed to have further improvements.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are schematic diagrams of a semiconductor device according to an embodiment of the present disclosure, respectively.

FIGS. 2A to 2D are schematic diagrams illustrating a method for manufacturing a semiconductor device according to an embodiment of the present disclosure.

FIGS. 3A to 3D are schematic diagrams illustrating a method for manufacturing a semiconductor device according to another embodiment of the present disclosure.

FIGS. 4A to 4D illustrate schematic diagrams illustrating a method for manufacturing a semiconductor device according to another embodiment of the present disclosure.

FIGS. 5A to 5D are schematic diagrams illustrating a method for manufacturing a semiconductor device according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

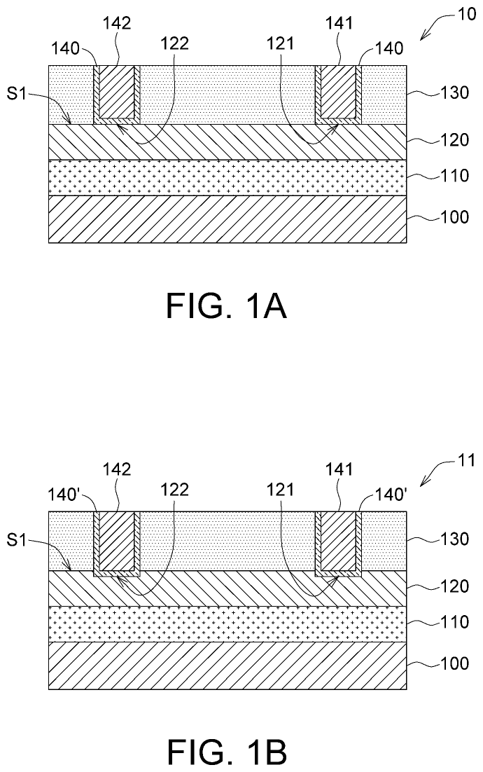

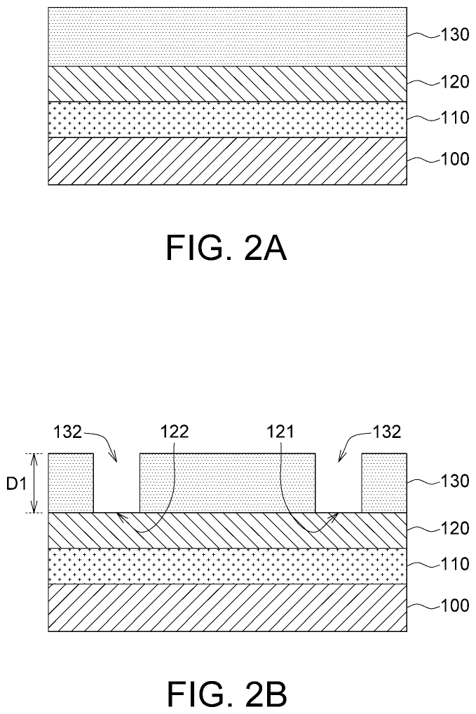

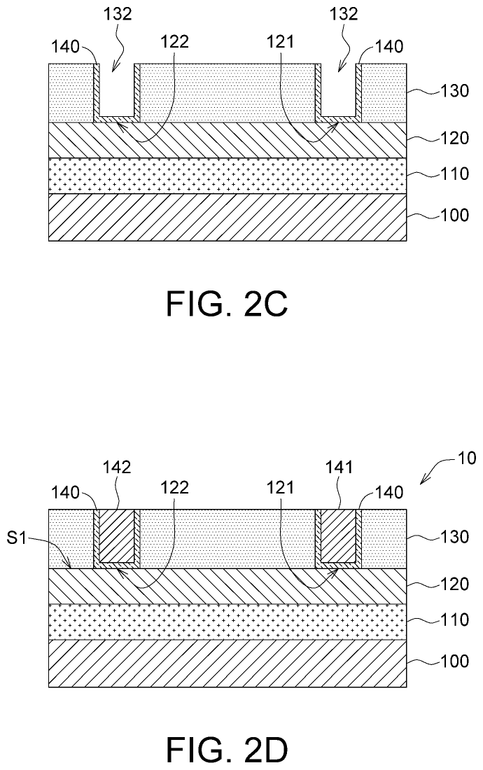

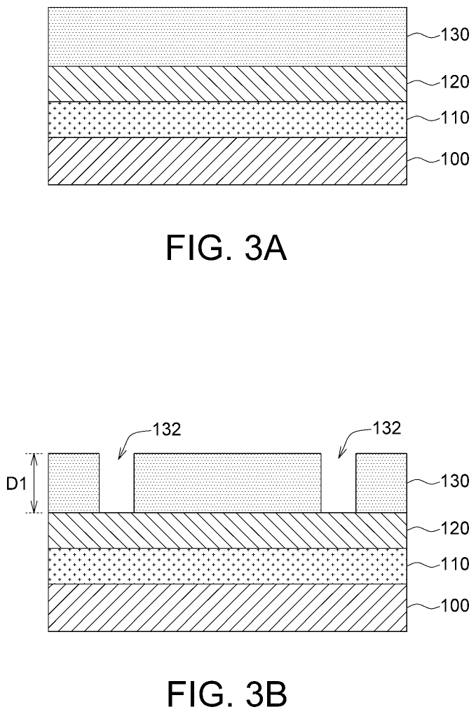

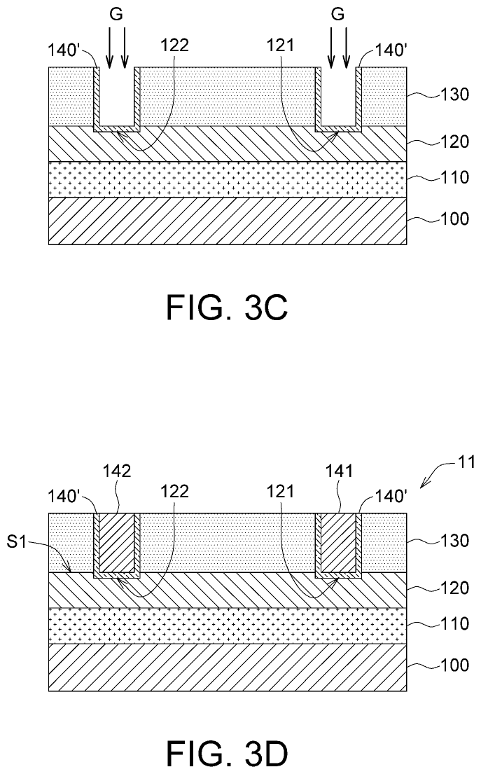

Please refer to FIGS. 1A and 1B. FIGS. 1A and 1B respectively show a schematic diagram of a semiconductor device 10, 11 according to an embodiment of the present disclosure. Although these embodiments take the thin film transistor having the bottom gate electrode 100 as an example, the present disclosure is not limited thereto, and can also be implemented by other embodiments. The semiconductor device 10 of FIG. 1A can be formed by the manufacturing method shown in FIGS. 2A to 2D, while the semiconductor device 11 of FIG. 1B can be formed by the manufacturing method shown in FIGS. 3A to 3D, the difference between the two embodiments is, in FIG. 1A, the protective interface layer 140 is formed on the two contact surfaces by deposition treatment, while in FIG. 1B, the protective interface layer 140 is included in the surface layers of the two contact surfaces by plasma treatment.

The semiconductor device 10, 11 includes a gate electrode 100, a gate insulating layer 110, an active layer 120, a dielectric layer 130, a source electrode 141 and a drain electrode 142. The gate insulating layer 110 is disposed between the gate electrode 100 and the active layer 120, the dielectric layer 130 is disposed on one side of the active layer 120, and the source electrode 141 and the drain electrode 142 pass through the dielectric layer 130 and are electrically connected to the active layer 120, wherein a first contact surface 121 is formed between the source electrode 141 and the active layer 120, and a second contact surface 122 is formed between the drain electrode 142 and the active layer 120, the first contact surface 121 and the second contact surface 122 are subjected to a plasma treatment or a deposition treatment to form a protection interface layer 140 or 140′.

The material of the gate electrode 100 includes chromium, molybdenum, copper, aluminum, tungsten, titanium or a combination thereof, but the disclosure is not limited thereto. The gate insulating layer 110 is formed on the gate electrode 100. The gate insulating layer 110 may be a dielectric material including silicon oxide (SiOx), aluminum oxide (AlOx), hafnium oxide:zirconium oxide (HfOx:ZrOx), hafnium oxide:aluminum oxide (HfOx:AlOx), hafnium oxide:oxide Lanthanum (HfOx:LaOx), hafnium oxide:silicon oxide (HfOx:SiOx), hafnium oxide:strontium oxide (HfOx:SrO), hafnium zirconium oxide (HZO) doped with cerium oxide (CeOx), etc. The active layer 120 is formed on the gate insulating layer 110, and the material of the active layer 120 includes monocrystalline silicon (a-Si), polycrystalline silicon (poly-Si) or metal oxide semiconductor, such as indium zinc oxide (IZO), indium gallium oxide (IGO), indium gallium zinc oxide (IGZO), tungsten oxide (IWO), tungsten zinc oxide (IWZO), etc.

FIGS. 2A to 2D show schematic diagrams illustrating a method for manufacturing the semiconductor device 10 according to an embodiment of the present disclosure, and FIGS. 3A to 3D show schematic diagrams illustrating a method for manufacturing the semiconductor device 11 according to another embodiment of the present disclosure. Referring to FIGS. 2A to 2D and FIGS. 3A to 3D, the manufacturing method of the semiconductor device 10, 11 includes the following steps. A gate electrode 100 is formed. A gate insulating layer 110 is formed on the gate electrode 100. An active layer 120 is formed on the gate insulating layer 110. A dielectric layer 130 is formed on the active layer 120, and the dielectric layer 130 is partially etched to form two vias 132 (see FIGS. 2B and 3B), and the two vias 132 expose a portion of the active layer 120, and the portion serves as two contact surfaces 121 and 122 for connecting the source electrode 141 and the drain electrode 142 subsequently deposited (see FIGS. 2D and 3D). The two contact surfaces 121 and 122 are subjected to a plasma process or a deposition process to form a protective interface layer 140 (see FIGS. 2C and 3C).

Referring to FIGS. 2A and 3A, the method for forming the gate electrode 100 and the gate insulating layer 110 is not particularly limited, and the types of metals for forming the gate electrode 100 are also not particularly limited. For example, in the formation process of the gate electrode 100, metals such as aluminum (Al) and copper (Cu) with low resistivity, or molybdenum (Mo), chromium (Cr), titanium (Ti) with high heat resistance or one of the alloys of these metals are preferably selected.

In addition, the gate electrode 100 may be a laminated gate electrode including multiple layers of metals. In addition, in the formation of the gate insulating layer 110, oxides such as SiOx, SiNx, AlOx, or HfOx can be selectively used, and a multilayer type in which a SiOx thin film and a SiNx thin film are continuously formed can be used as the gate insulating layer 110, for example. The multilayer insulating film can increase the dielectric constant. Therefore, the total film thickness of the multilayer gate insulating layer 110 can be reduced. In FIGS. 2A and 3A, although the gate insulating layer 110 is shown as a single layer, the gate insulating layer 110 may include multiple insulating layers, and each insulating layer may include a different dielectric material.

The active layer 120 is, for example, an oxide semiconductor layer, which can be formed by, for example, direct current (DC) sputtering or radio frequency (RF) sputtering. In the DC sputtering or RF sputtering, a sputtering target having the same composition as the oxide semiconductor of the active layer 120. Alternatively, the active layer 120 may be formed by a co-sputtering method using a plurality of sputtering targets.

In addition, a dielectric layer 130 is formed on the active layer 120, and the dielectric layer 130 may be silicon oxide (SiOx), aluminum oxide (AlOx), or the like. Two vias 132 are formed in the dielectric layer 130 by dry etching (e.g., plasma etching), and the two vias 132 expose a portion of the active layer 120 for connecting two contact surfaces 121 and 122 of the source electrode 141 and the drain electrode 142 in subsequent process.

Referring to FIGS. 2B and 3B, the active layer 120 has a first contact surface 121 and a second contact surface 122 in the two vias 132, and then, in FIGS. 2C and 3C, the first contact surface 121 and the second contact surface 122 are subjected to a plasma treatment or a deposition treatment to form the protective interface layer 140. That is, before the source electrode 141 and the drain electrode 142 are deposited in the vias 132, a protective interface layer 140 is formed on the first contact surface 121 and the second contact surface 122 or included in the surface layer of the first contact surface 121 and the second contact surface 122.

The material of the protective interface layer 140 includes zinc oxide (ZnO); gallium oxide (GaO); indium oxide (InO); nickel oxide (NiO); titanium oxide (TiO); cobalt (Co); nickel (Ni); titanium nitride (TiN); tantalum nitride (TaN); titanium (Ti); carbon (C); fluorine (F), etc. The protective interface layer 140 is formed by, for example, physical vapor deposition (PVD), chemical vapor deposition (CVD) or atomic layer deposition (ALD). PVD deposition usually contains sputtering deposition, cathodic arc deposition, electron beam deposition, etc.

Please refer to FIG. 2C, take the titanium nitride (TiN) thin film deposition method to form the protective interface layer 140 as an example, pure titanium is sublimed and react with nitrogen (N₂) in a high-energy vacuum environment to generate the protective Interface layer 140 of titanium nitride. Alternatively, at a high temperature, the titanium tetrachloride (TiCl₄)-nitrogen mixture is reacted with an ammonia-hydrogen mixture to obtain the protective interface layer 140 of titanium nitride, or the titanium-hydrogen-nitrogen mixture is heated to a high temperature and pass through graphite, titanium nitride is deposited in the vias 132 to form a protective interface layer 140 after cooling.

As shown in FIG. 2C, the protective interface layer 140 is formed on the side walls Wi of the two vias 132 and on the top of the two contact surfaces 121 and 122. The protective interface layer 140 can avoid plasma damage to the active layer 120 caused by the plasma gas. The reason for the plasma damage is that the two contact surfaces 121 and 122 of the active layer 120 (e.g. oxide semiconductor) are bombarded by plasma and the oxygen ions are released (bond breaking) to generate oxygen vacancy. The protective interface layer 140 is, for example, zinc oxide (ZnO); gallium oxide (GaO); indium oxide (InO); nickel oxide (NiO); titanium oxide (TiO) or other oxides, which have high bonding force with oxygen ions, which can prevent oxygen ions from being bombarded by plasma and released (bond breaking).

The thickness of the protective interface layer 140 is preferably between 0.1 to 2 nm, such as 0.5 nm or 1 nm, but it is not limited in the present disclosure.

Referring to FIG. 2D, the source electrode 141 and the drain electrode 142 are formed in the two vias 132 by PVD deposition, wherein the protective interface layer 140 is formed on the side walls Wi of the two vias 132 and on the top of the two contacts surfaces 121 and 122, so that the source electrode 141 and the drain electrode 142 are not in direct contact with the two contact surfaces 121 and 122. A channel region is formed between the source electrode 141 and the drain electrode 142, and the gate electrode 100 is disposed under the channel region for applying a gate voltage to control the current flowing through the channel. The types of the source electrode 141 and the drain electrode 142 are not particularly limited, and common electrode materials can be used. For example, the source electrode 141 and the drain electrode 142 may be made of Molybdenum (Mo), Chromium (Cr), Titanium (Ti) and the like or alloys. Among these materials, Cu or Cu alloy is preferably used in view of low resistivity.

The formation method of the source electrode 141 and the drain electrode 142 is not limited, for example, a metal film is formed by a magnetron sputtering method or a radio frequency (RF) sputtering method, and then a wet etching is performed with an etchant of hydrogen peroxide, phosphoric acid, nitric acid or acetic acid to remove a portion of the metal film above the vias 132, thereby forming the source electrode 141 and the drain electrode 142.

Please refer to FIGS. 3A to 3D, which show schematic diagrams illustrating a method for manufacturing the semiconductor device 11 according to another embodiment of the present disclosure. In addition to forming a protective interface layer 140 by PVD or ALD deposition, in this embodiment, before forming the source electrode 141 and the drain electrode 142, a protective interface layer 140′ is formed in the two contact surfaces 121 and 122 by plasma treatment of one of the gases G such as O₃, CO₂, NF₃, N₂O, etc. The protective interface layer 140′ can inhibit the plasma damage to the active layer 120 caused by the subsequent plasma gas.

In some embodiments, for example, thin films such as aluminum oxide (AlOx) and hafnium oxide (HfOx) with high dielectric constant may be used as the material of the dielectric layer 130, and the plasma treatment of one gas G such as O₃, CO₂, NF₃, N₂O, etc. is performed through the vias 132 in the dielectric layer 130 and/or the active layer 120, to improve the defect content of the interfaces between the source/drain electrodes and the active layer 120 and the dielectric layer 130, and to improve the electrical stability of the transistor.

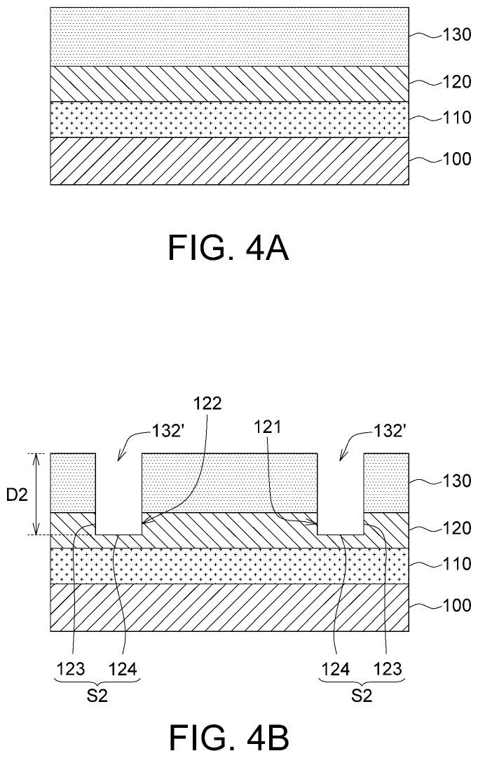

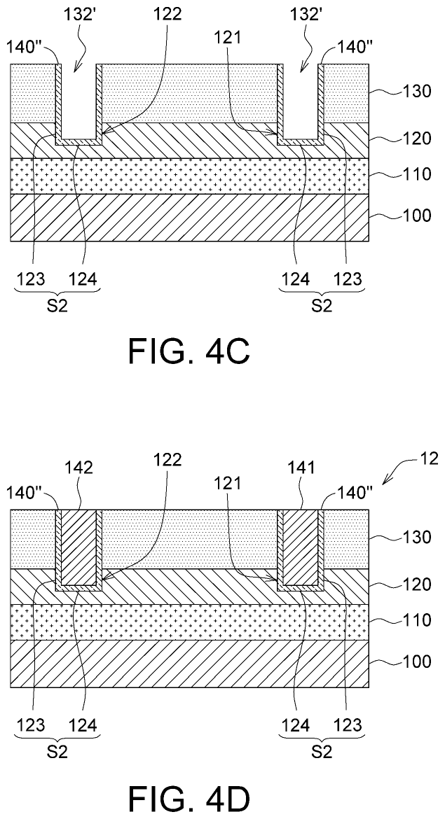

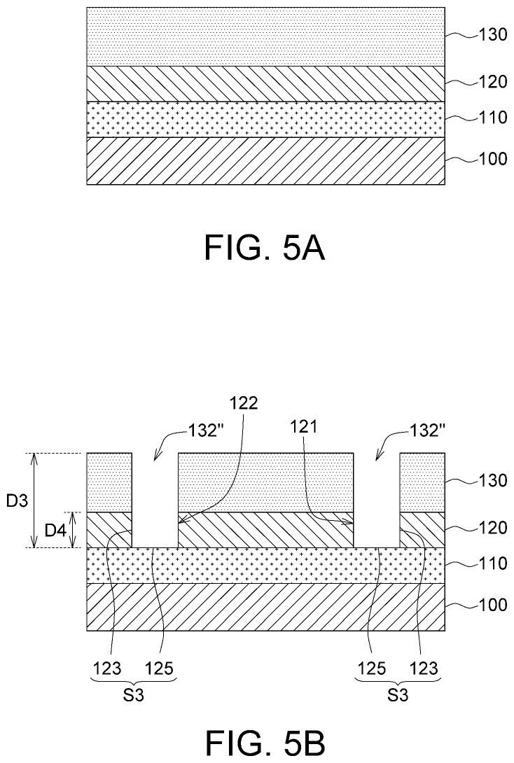

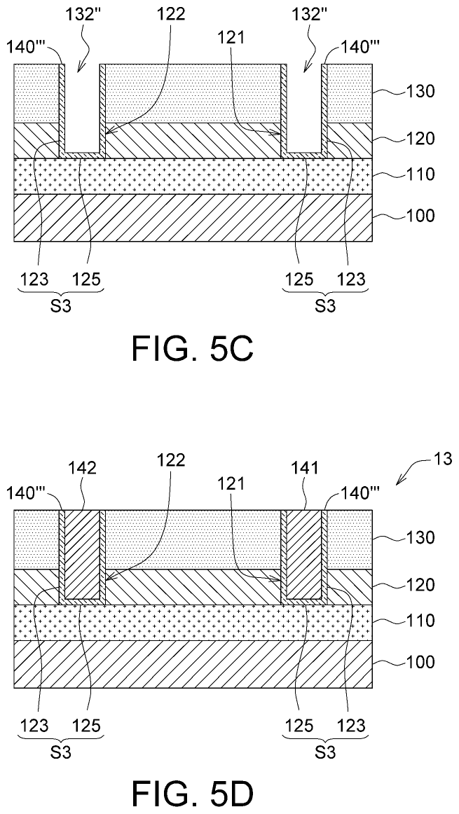

In addition, for different applications of semiconductor processes, there are various types of etching the dielectric layer 130 to form vias, and three common semiconductor processes are described below. First, the depth D1 of the etched vias 132 in the first semiconductor process is, for example, equal to the thickness of the dielectric layer 130, the source electrode 141 and the drain electrode 142 do not pass through the active layer 120, the first contact surface 121 and the second contact surface 122 is formed with the protective interface layer 140 or 140′ in the interface S1 between the active layer 120 and the dielectric layer 130 (see FIGS. 2A to 2D and FIGS. 3A to 3D). The depth D2 of the etched vias 132′ in the second semiconductor process is, for example, equal to the thickness of the dielectric layer 130 and a half of the thickness of the active layer 120, wherein the source electrode 141 and the drain electrode 142 partially embedded into the active layer 120, and the active layer 120 has a concave surface S2, the first contact surface 121 and the second contact surface 122 is formed with the protective interface layer 140″ in the concave surface S2 (see FIGS. 4A to 4D). The depth D3 of the etched vias 132″ in the third semiconductor process is, for example, equal to the thickness of the dielectric layer 130 and the thickness of the active layer 120, wherein the source electrode 141 and the drain electrode 142 completely pass through the active layer 120, and the active layer 120 has a contact hole S3, and the protective interface layer 140′″ is disposed in the contact hole S3 (see FIGS. 5A to 5D).

The manufacturing method of the semiconductor device 12 in FIGS. 4A to 4D and the manufacturing method of the semiconductor device 13 in FIGS. 5A to 5D are substantially the same as the manufacturing methods of the semiconductor devices 10 and 11 in FIGS. 2A to 2D and FIGS. 3A to 3D, and will not be repeated here. The difference is that the etched vias 132 in FIGS. 2B to 2C and FIGS. 3B to 3C do not pass through the active layer 120, and the protective interface layer 140 or 140′ between the active layer 120 and the two electrodes is disposed at the interface S1 of the active layer 120 and the dielectric layer 130; the etched vias 132′ in FIGS. 4B to 4C are further formed in the active layer 120, so that the active layer 120 has a concave surface S2, The protective interface layer 140″, between the active layer 120 and the two electrodes, is substantially disposed on the inner wall 123 and the bottom wall 124 of the concave surface S2 of the active layer 120, and the depth of the concave surface S2 is less than the thickness of the active layer 120, for example, equal to or greater than a half of the thickness of the active layer 120; the etched vias 132″ in FIG. 5B to 5C completely penetrates the active layer 120, so that the active layer 120 has a contact hole S3, and the protective interface layer 140′″, between the active layer 120 and the two electrodes, is substantially disposed on the inner wall 123 of the contact hole S3 and the top surface 125 of the gate insulating layer 110, and the depth D4 of the contact hole S3 is substantially equal to the thickness of the active layer 120.

Since the semiconductor devices 10-13 have higher requirements on the carrier mobility of the thin film transistor, and at the same time, in order to reduce power consumption, reduction of the operating voltage of the thin film transistor is also an important issue. In some embodiments, different plasma treatments can be performed in the vias 132, 132′,132″ of the dielectric layer 130 and/or the active layer 120 to improve the defect content of the interface between the two electrodes and the active layer 120 and the dielectric layer 130 and to improve the electrical stability of the thin film transistor.

In addition, the semiconductor devices 10-13 treated by plasma using O₃, CO₂, NF₃, N₂O, etc., have a small threshold voltage shift. The X-ray spectrum results show that plasma treatment of O₃, CO₂, NF₃, N₂O, etc. can inhibit the generation of oxygen vacancies in the active layer 120 under the positive gate bias stress, thereby increasing the electrical stability of the semiconductor device. At the same time, under the negative gate bias, holes will be captured by interface defects and electrons captured by charged oxygen vacancies in the active layer 120 will cause the threshold voltage shift of the semiconductor device successively, however, the instability behavior can be eliminated with plasma treatment on the active layer 120 in the present disclosure. Therefore, plasma treatment such as O₃, CO₂, NF₃, N₂O, etc. performed in the vias 132, 132′,132″ can reduce the oxygen vacancies in the dielectric layer 130 and/or the active layer 120, reduce the amount of threshold voltage shift, and increase electrical stability of the semiconductor devices 10-13.

The present disclosure relates to a semiconductor device and a manufacturing method thereof for improving the reliability of the semiconductor device. Based on the present disclosure, the problem of oxygen vacancies generated on the surface of the active layer due to plasma damage caused by CVD or PVD can be improved by using a plasma treatment or a deposition treatment to form a protective interface layer for the active layer, so that the generation of oxygen vacancies in the active layer under the positive gate bias stress can be inhibited, thereby increasing the electrical stability of the semiconductor device.

In some embodiments of the present disclosure, a semiconductor device is provided, which includes a gate electrode, a gate insulating layer, an active layer, a dielectric layer, a source electrode, and a drain electrode. The gate insulating layer is disposed between the gate electrode and the active layer, the dielectric layer is disposed on one side of the active layer, and the source electrode and the drain electrode pass through the dielectric layer to be electrically connected with the active layer, wherein a first contact surface is formed between the source electrode and the active layer, a second contact surface is formed between the drain electrode and the active layer, the first contact surface and the second contact are subjected to a plasma treatment or a deposition treatment to form a protective interface layer.

In some embodiments of the present disclosure, a method for manufacturing a semiconductor device is provided, which includes the following steps. A gate electrode is formed; a gate insulating layer is formed on the gate electrode; an active layer is formed on the gate insulating layer; a dielectric layer is formed on the active layer, the dielectric layer is partially etched to form two vias, the two vias expose a portion of the active layer and the portion serves as two contact surfaces for connecting a source electrode and a drain electrode subsequently; and the two contact surfaces are subjected to a plasma treatment or a deposition treatment to form a protective interface layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a gate electrode;
a gate insulating layer;
an active layer, wherein the gate insulating layer is disposed between the gate electrode and the active layer;
a dielectric layer disposed on a side of the active layer;
a source electrode; and
a drain electrode, wherein the source electrode and the drain electrode are electrically connected to the active layer through the dielectric layer,
wherein a first contact surface is formed between the source electrode and the active layer, a second contact surface is formed between the drain electrode and the active layer, and the first contact surface and the second contact surface are subjected to a plasma treatment to form a protective interface layer.

2. The semiconductor device according to claim 1, wherein the source electrode and the drain electrode do not pass through the active layer, and the protective interface layer is at least disposed at an interface between the active layer and the dielectric layer.

3. The semiconductor device according to claim 1, wherein the source electrode and the drain electrode are partially embedded into the active layer, the active layer has a concave surface, and the protective interface layer is at least disposed in the concave surface.

4. The semiconductor device according to claim 1, wherein the source electrode and the drain electrode completely pass through the active layer, the active layer has a contact hole, and the protective interface layer is at least disposed in the contact hole.

5. The semiconductor device according to claim 1, wherein the plasma treatment comprises one of plasma treatments of O₃, CO₂, NF₃, N₂O, and the protective interface layer is included in the first and second contact surfaces through the plasma treatment.

6. A semiconductor device, comprising:
a gate electrode;
a gate insulating layer;
an active layer, wherein the gate insulating layer is disposed between the gate electrode and the active layer;
a dielectric layer disposed on a side of the active layer;
a source electrode; and
a drain electrode, wherein the source electrode and the drain electrode are electrically connected to the active layer through the dielectric layer,
wherein a first contact surface is formed between the source electrode and the active layer, a second contact surface is formed between the drain electrode and the active layer, and the first contact surface and the second contact surface are subjected to a deposition treatment to form a protective interface layer.

7. The semiconductor device according to claim 6, wherein the source electrode and the drain electrode do not pass through the active layer, and the protective interface layer is at least disposed at an interface between the active layer and the dielectric layer.

8. The semiconductor device according to claim 6, wherein the source electrode and the drain electrode are partially embedded into the active layer, the active layer has a concave surface, and the protective interface layer is at least disposed in the concave surface.

9. The semiconductor device according to claim 6, wherein the source electrode and the drain electrode completely pass through the active layer, the active layer has a contact hole, and the protective interface layer is at least disposed in the contact hole.

10. The semiconductor device according to claim 6, wherein the protective interface layer comprises a material selected from zinc oxide (ZnO), gallium oxide (GaO), indium oxide (InO), nickel oxide (NiO), titanium oxide (TiO) or a combination thereof.

11. The semiconductor device of claim 6, wherein the protective interface layer comprises a material selected from cobalt (Co), nickel (Ni), titanium nitride (TiN), tantalum nitride (TaN), titanium (Ti), carbon (C), fluorine (F) or a combination thereof.

12. The semiconductor device of claim 6, wherein the protective interface layer is formed by physical vapor deposition, chemical vapor deposition or atomic layer deposition, and the protective interface layer is formed on top of the first and second contact surfaces by the deposition treatment.

13. A method for manufacturing a semiconductor device, comprising:
forming a gate electrode;
forming a gate insulating layer on the gate electrode;
forming an active layer on the gate insulating layer;
forming a dielectric layer on the active layer, wherein the dielectric layer is partially etched to form two vias, and the two vias expose a portion of the active layer and the portion serves as two contact surfaces for connecting a source electrode and a drain electrode subsequently; and
the two contact surfaces are subjected to a plasma treatment or a deposition treatment to form a protective interface layer.

14. The method for manufacturing a semiconductor device according to claim 13, wherein the two vias do not pass through the active layer, and the protective interface layer is at least disposed at an interface between the active layer and the dielectric layer.

15. The method for manufacturing a semiconductor device according to claim 13, wherein the two vias partially embedded into the active layer, the active layer has a concave surface, and the protective interface layer is disposed in the concave surface of the active layer, a depth of the concave surface is less than a thickness of the active layer.

16. The method for manufacturing a semiconductor device according to claim 13, wherein the two vias completely pass through the active layer, the active layer has a contact hole, the protective interface layer is disposed in the contact hole, and a depth of the contact hole is equal to a thickness of the active layer.

17. The method for manufacturing a semiconductor device according to claim 13, wherein the protective interface layer comprises a material selected from zinc oxide (ZnO), gallium oxide (GaO), indium oxide (InO), nickel oxide (NiO), titanium oxide (TiO) or a combination thereof.

18. The method for manufacturing a semiconductor device according to claim 13, wherein the protective interface layer comprises a material selected from cobalt (Co), nickel (Ni), titanium nitride (TiN), tantalum nitride (TaN), titanium (Ti), Carbon (C), Fluorine (F) or a combination thereof.

19. The method for manufacturing a semiconductor device according to claim 13, wherein the plasma treatment comprises one of plasma treatments of O₃, CO₂, NF₃, N₂O, and the protective interface layer is included in the two contact surfaces through the plasma treatment.

20. The method for manufacturing a semiconductor device according to claim 13, wherein the deposition treatment comprises forming the protective interface layer by physical vapor deposition, chemical vapor deposition or atomic layer deposition, and the protective interface layer is formed on top of the two contact surfaces by the deposition treatment.
